(19) United States
(12) Patent Application Publication
(10) Pub. No.: US 2023/0247771 A1
(43) Pub. Date: Aug. 3, 2023

(54) HIGH SPEED DATA MODULE FOR HIGH LIFE CYCLE INTERCONNECT DEVICE

(71) Applicant: Virginia Panel Corporation, Waynesboro, VA (US)

(72) Inventors: Randall Garman, Waynesboro, VA (US); Christopher Church-Diciccio, Waynesboro, VA (US); Daryll Ashby, Weyers Cave, VA (US)

(21) Appl. No.: 18/103,545

(22) Filed: Jan. 31, 2023

Related U.S. Application Data
(60) Provisional application No. 63/305,456, filed on Feb. 1, 2022.

(51) Int. Cl. H05K 3/30; H05K 13/00

(52) U.S. Cl. CPC H05K 3/303; H05K 13/0069

(57) ABSTRACT

A high-speed data contact set having a housing with a hollow body having a top, a bottom, a front, a rear, and first side and a second side; a plurality of protective arms extending from the front of said hollow body for protecting contact beams of a termination subassembly inserted into said insert housing. The termination subassembly in said insert shroud, has a plurality of pairs of contact beams, a termination subassembly body molded on and around a central portion of the plurality of pairs of contacts, a printed circuit board connected to the pairs of contacts, and a plurality of wires each having a stripped end soldered to said printed circuit board. One end of each of said plurality of pairs of contacts is soldered to said printed circuit board, and a shield strap covers said stripped end of wire of said plurality of wires.

### CROSS-REFERENCE TO RELATED APPLICATIONS

The present application claims the benefit of the filing date of U.S. Provisional Patent Application Ser. No. 63/305,456 filed by the present inventors on Feb. 1, 2022.

The aforementioned provisional patent application is hereby incorporated by reference in its entirety.

### STATEMENT REGARDING FEDERALLY SPONSORED RESEARCH OR DEVELOPMENT

None.

### BACKGROUND OF THE INVENTION

### Field Of The Invention

The present invention relates to high-speed data contacts, and more particularly, high speed contact sets or modules for use with high life-cycle or mass interconnect devices.

### Brief Description Of The Related Art

A variety of high-speed data contacts have been developed and used along with various modules for housing such high-speed data contacts. Examples include those disclosed in U.S. Patent Application Publication No. 2013/0102199, entitled “Hermaphroditic Interconnect System,” U.S. Patent Application Publication No. 2011/0177699 entitled “Backplane Cable Interconnection,” U.S. Patent Application Publication No. 2010/0248522 entitled “Electrical Cable Connection Latch System” and U.S. Pat. No. 7,316,579, entitled “Zero Insertion Force Cable Interface.” Additional high speed data contact systems are known, for example, as the “FCI Examax.” While these prior high speed data contact systems had various advantages, none were specifically adapted for use in high life cycle systems designed to perform for thousands or tens of thousands of connection cycles or for mass interconnect systems.

A variety of high life cycle and mass interconnect devices for use with various contacts are known. One example of a conventional high life-cycle interconnect device or interface system is the mass interconnect device disclosed in U.S. Pat. No. 4,329,005, entitled “Slide Cam Mechanism for Positioning Test Adapter in Operative Relationship with a Receiver.” Other prior art engagement systems include those disclosed in U.S. Pat. Nos. 5,966,023, 5,562,458, 7,297,014, U.S. Patent Application Publication No. 2010/0194417 and U.S. Pat. No. 8,348,693.

Further, U.S. Pat. No. 9,246,286 discloses a hermaphroditic high speed data contact set having an insert shroud and a termination subassembly. A plurality of protective arms extend from its front to protect contact beams of the termination subassembly and provide multi-stage pre-alignment of contacts during engagement. A plurality of raised bosses engaged with a plurality of hollows in the bottom of an adjacent insert shroud to allow stacking of contact sets. A pair of latches lock the insert shroud into a module after insertion. A pair of keying members on the sides of contact set prevent incorrect insertion of a contact set into a module. U.S. Pat. No. 9,685,727 further discloses a right-angle termination insert.

### SUMMARY OF THE INVENTION

In a preferred embodiment, the present invention is a high-speed data contact set having a housing with a hollow body having a top, a bottom, a front, a rear, and first side and a second side; a plurality of protective arms extending from the front of said hollow body for protecting contact beams of a termination subassembly inserted into said insert housing. The termination subassembly in said insert shroud, has a plurality of pairs of contact beams, a termination subassembly body molded on and around a central portion of the plurality of pairs of contacts, a printed circuit board connected to the pairs of contacts, and a plurality of wires each having a stripped end soldered to said printed circuit board. One end of each of said plurality of pairs of contacts is soldered to said printed circuit board, and a shield strap covers said stripped end of wire of said plurality of wires

Still other aspects, features, and advantages of the present invention are readily apparent from the following detailed description, simply by illustrating a preferable embodiments and implementations. The present invention is also capable of other and different embodiments and its several details can be modified in various obvious respects, all without departing from the spirit and scope of the present invention. Accordingly, the drawings and descriptions are to be regarded as illustrative in nature and not as restrictive. Additional objects and advantages of the invention will be set forth in part in the description which follows and in part will be obvious from the description or may be learned by practice of the invention.

### BRIEF DESCRIPTION OF THE DRAWINGS

For a more complete understanding of the present invention and the advantages thereof, reference is now made to the following description and the accompanying drawings, in which:

FIG. 1 is a perspective view of a sheet of high-speed contacts in accordance with a preferred embodiment of the present invention.

FIG. 2 is a perspective view of a sheet of high-speed contacts cut into a strip of 8 contacts in accordance with a preferred embodiment of the present invention.

FIG. 3 is a perspective view of a molded termination subassembly for a high-speed data contact set in accordance with a preferred embodiment of the present invention.

FIG. 4A is a front perspective view of a molded termination subassembly for a high-speed data contact set soldered to a printed circuit board (PCB) in accordance with a preferred embodiment of the present invention.

FIG. 4B is a rear perspective view of a molded termination subassembly for a high-speed data contact set soldered to a printed circuit board (PCB) in accordance with a preferred embodiment of the present invention.

FIG. 5 is a perspective view of a molded termination subassembly for a high-speed data contact set soldered to a printed circuit board (PCB) with wiring connected to the printed circuit board in accordance with a preferred embodiment of the present invention.

FIG. 6 is a perspective view of a molded termination subassembly for a high-speed data contact set soldered to a printed circuit board (PCB) with wiring connected to the printed circuit board in a housing with potting material in accordance with a preferred embodiment of the present invention.

FIG. 7 is a perspective view of a shroud or housing for a high-speed data contact set in accordance with a preferred embodiment of the present invention.

### DETAILED DESCRIPTION OF THE PREFERRED EMBODIMENTS

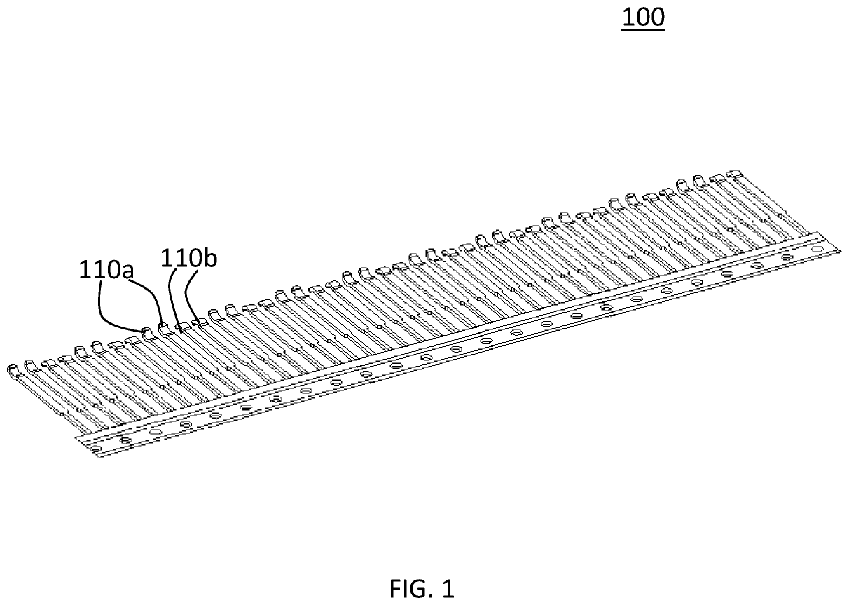

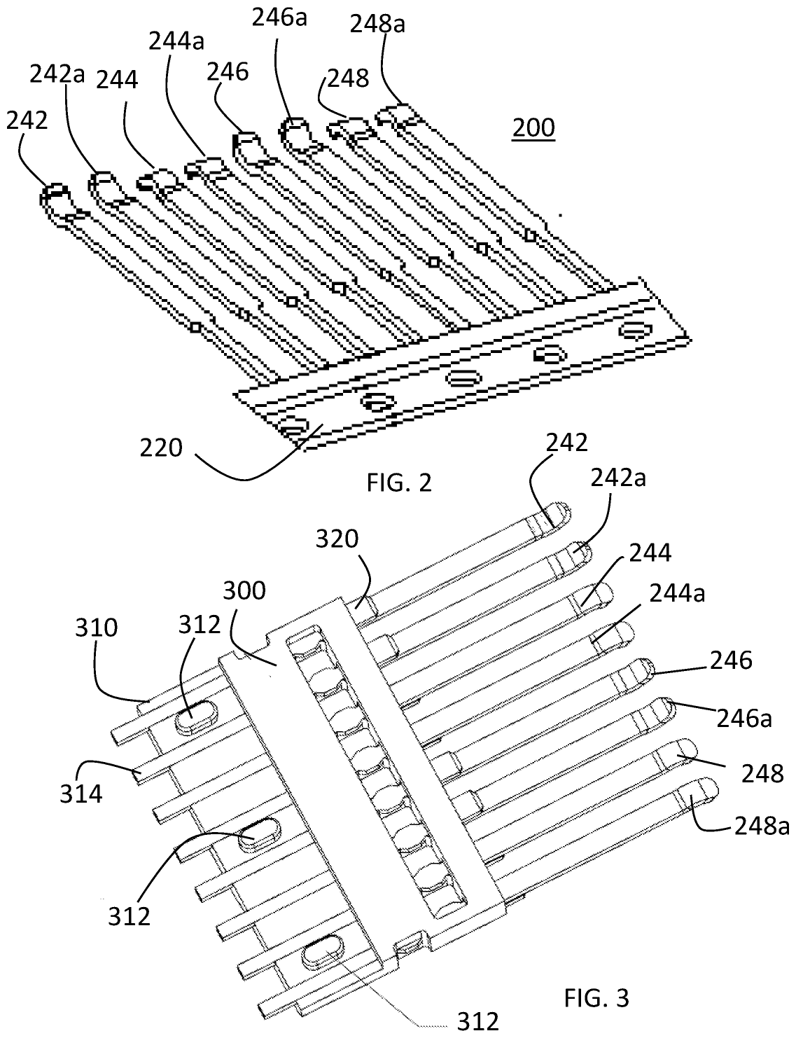

A high-speed data contact set according to the present invention is described with reference to the figures. A sheet 100 of contacts having alternating contact pairs 110a, 110b as shown in FIG. 1 are formed by known means. On the sheet, the contacts are formed in a load balanced alternating two up/two down pattern. This pattern allows the high-speed data contact set to be hermaphroditic such that the same high speed data contact set or chiclet may be used on both the receiver side and test adapter side of an interface and can connect to one another. A set of a plurality of contacts, eight contacts 242, 242a, 244a, 244, 246, 246a, 248a, 248 in the preferred embodiment, is cut from the sheet 210 as shown in FIG. 2, the set having the two up/two down pattern of contacts. The eight contact beams in the set initially are connected to one another by shield 220. The eight contact beams are in a row (wafer shape) and can carry differential signal pairs at speeds of 10 Gigabits per second.

An overmolded insulator or termination subassembly body 300 is molded on and around a central portion of the contacts as shown in FIG. 3. The termination subassembly body 300 is formed of a non-conductive or insulating material such as plastic. The termination subassembly body 300 has a support member 310 for supporting the contact ends that are connected together by the shield 220 and may have support members 320 for supporting the free ends of the contacts. The molded termination subassembly body 300 further has a plurality of bosses 312 to align the termination subassembly with a printed circuit board (PCB). After molding of the termination subassembly body 300 onto the contact set, the contacts, 242, 242a, 244, 244a, 246, 246a, 248, and 248a, are disconnected from the shield 220 leaving a plurality of contact tips 314 for PCB termination. The contacts, however, are held in place by the termination subassembly body 300. The termination subassembly body 300 further has an opening or latch feature 340 for securing the termination subassembly body 300 to a housing or shroud 700 that has a corresponding feature 760 for mating with the latch feature 340.

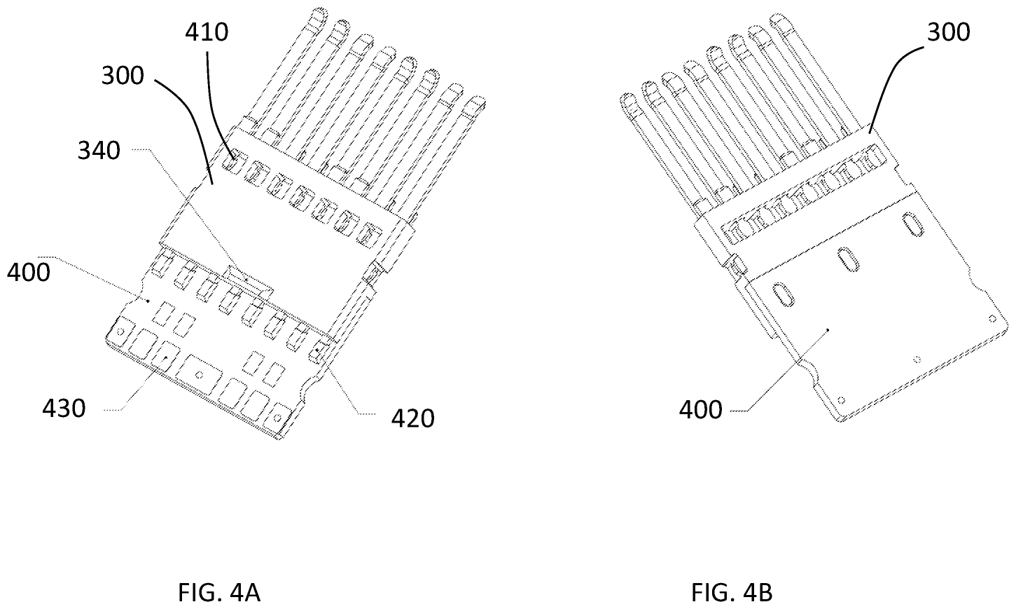

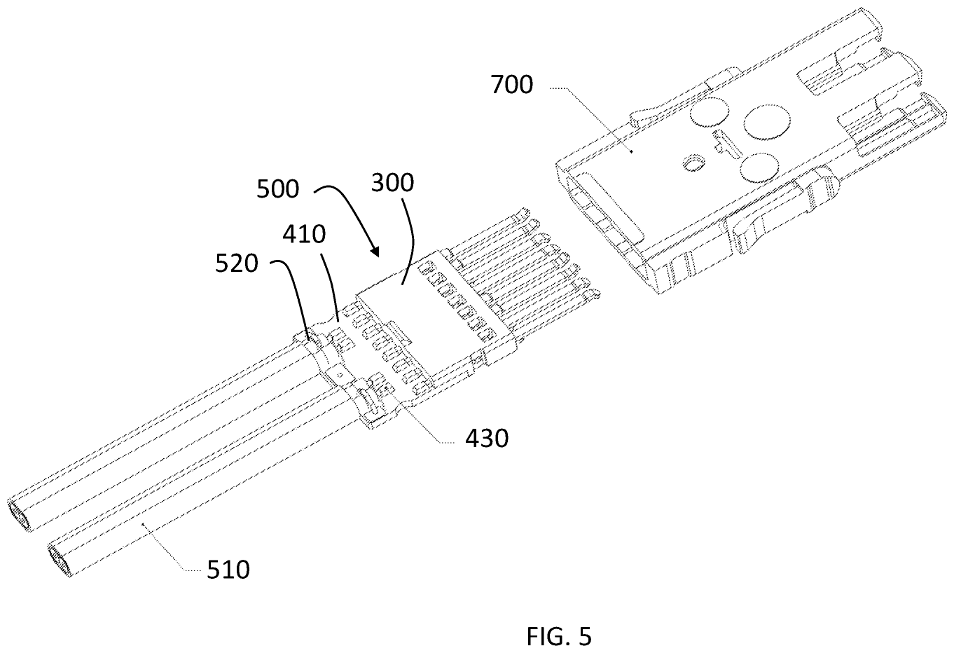

A printed circuit board (PCB) 400 is integrated into the contact set, as shown in FIGS. 4A and 4B. The support member 310 has three bosses 312 that are used to align a PCB with the contacts. The PCB board 400 will have mating features (openings or holes) 410 corresponding to the three PCB alignment bosses 312. The contacts 242, 242a, 244, 244a, 246, 246a, 248, and 248a, are soldered to the PCB board 400 to form solder connections 420 between the PCB board 400 and the contact tips 314. The PCB 400 can be customized for various wire types, which provides improved signal integrity thru reduced lengths of unshielded wire.

Wires 510 are soldered to the PCB at solder pads 430. The exposed portions of the wires 510 between the insulator on the wires and the PCB contacts is covered with a shield (ground) strap 520 that provide enhanced shielding and improved efficiency. The present invention provides improved signal integrity thru a reduced length of unshielded wire.

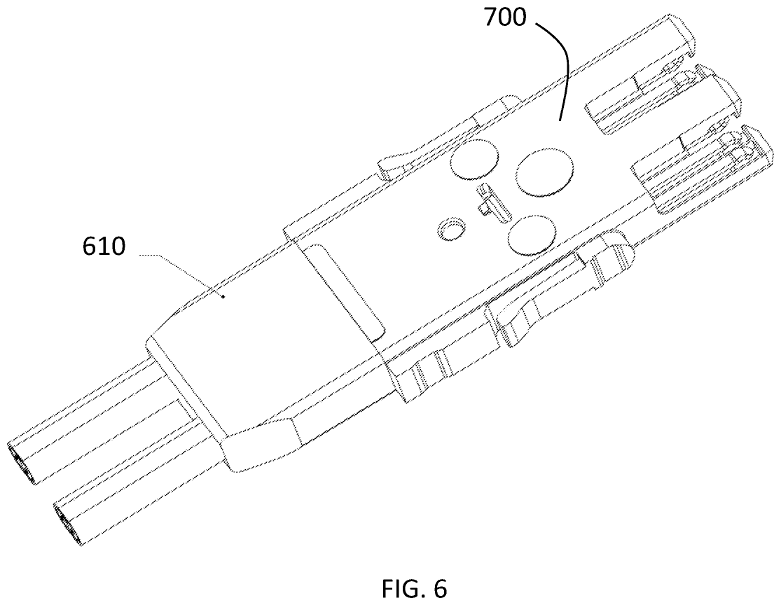

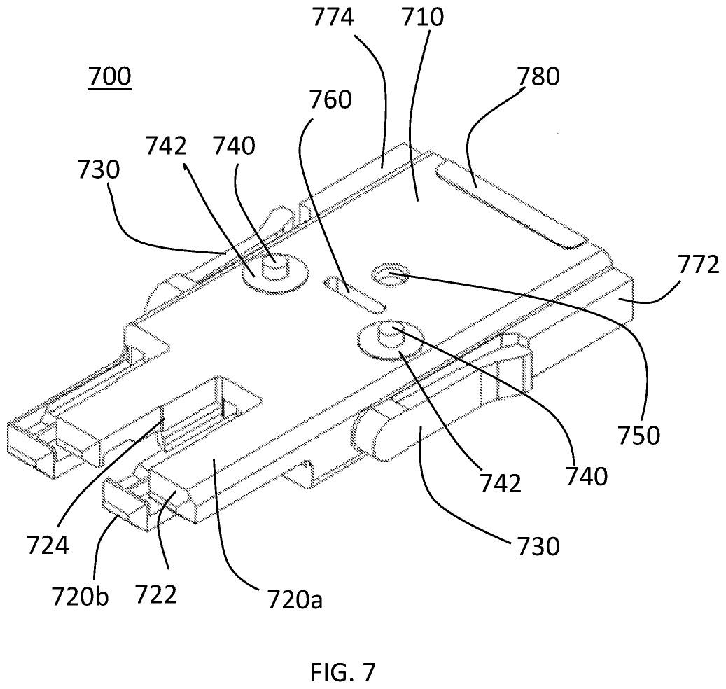

As shown in FIG. 6, the termination subassembly 500 is inserted into a housing 700 and potting material 610 is added to provide strain relief from the solder terminations. The high-speed data contact set, sometimes referred to as a chiclet, of a preferred embodiment of the present invention has a housing or shroud 700, such as is disclosed in U.S. Pat. No. 9,246,286, which in hereby incorporated by reference in its entirety, that includes multi-stage lead-in features and controlled float to pre-align contacts during engagement and thereby extends the cycle life of the contacts. The housing, shown in FIG. 7, is formed, for example, from a non-conductive material such as plastic. The housing 700 has a hollow body 710 having a plurality of protective arms 720a, 720b, 720c, and 720d extending from the distal portion of the body 710. The end of each protective arm 720a, 720b, 720c, and 720d has one or more beveled or angles edges 722 for providing a first stage of pre-alignment of contacts during engagement, for example, with another chiclet. On each side of each protective arm there is an angled shoulder 724 for providing a second stage of pre-alignment of contacts. The housing body 710 has a latch 730 on each side for holding the latch in a module after insertion. The latches 730 are biased away from the body 710 and have angled portions 732 extending away from the hollow body 710. The portions 732 may include beveled or angled corners and edges to prevent snagging and/or breakage when the shroud is removed from a module. The latches make the insert shrouds individually removable from a module of a receiver or test adapter frame. Also on each side, the housing body 710 has keying members 772, 774. The two module keying members 772 and 774 are of different sizes, thereby allowing insertion of the chiclet into a module in only one orientation, thereby preventing human errors in setting up an interface system. On top of the housing body 710 are two raised bosses 740 for providing alignment of the housing body 710 with an adjacent housing body when a plurality of chiclets are stacked together. At the base of each raised boss 740 is an annular spacing ridge 742. The top of the housing body 710 further has a hole 750 through which potting material may be injected. Also on the top of the housing body 710 is a slot 760 that may be used, for example, to release another connector that has been inserted into the rear of the insert shroud or housing. At the proximal end, the housing body 710 has a ridge or raised portion 780 corresponding to the height of the annular ridges 742.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described to explain the principles of the invention and its practical application to enable one skilled in the art to utilize the invention in various embodiments as are suited to the particular use contemplated. It is intended that the scope of the invention be defined by the claims appended hereto and their equivalents. The entirety of each of the aforementioned documents is incorporated by reference herein.

What is claimed is:

1. A high-speed data contact set comprising:
a housing comprising:
a hollow body having a top, a bottom, a front, a rear, and first side and a second side;
a plurality of protective arms extending from the front of said hollow body for protecting contact beams of a termination subassembly inserted into said insert shroud;
a termination subassembly in said insert shroud, said termination assembly comprising:
a plurality of pairs of contact beams, the contact beams in each pair being of the same orientation and the pairs of contact beams having alternating orientations;
a termination subassembly body molded on and around a central portion of the plurality of pairs of contacts, the termination subassembly body having a support member for supporting one end of each of said plurality of pairs of contacts, said support member having a plurality of alignment bosses;
a printed circuit board, said printed circuit board having a plurality of holes for aligning with said alignment bosses in said support member, wherein said one end of each of said plurality of pairs of contacts is soldered to said printed circuit board;
a plurality of wires each having a stripped end soldered to said printed circuit board; and
a shield strap covering said stripped end of wire of said plurality of wires.

2. The high-speed data contact set according to claim 1, wherein said termination subassembly body has a latch feature for securing said termination subassembly body to said housing.
